(19) United States
(12) Patent Application Publication
(10) Pub. No.: US 2019/0052025 A1
(43) Pub. Date: Feb. 14, 2019

(54) SMART ACTIVE CONNECTOR

(71) Applicant: INTERLEMO HOLDING S.A., Ecublens (CH)

(72) Inventors: Serge Buechli, Lausanne (CH); Alexandre Patenaude, Thonon-les-Bains (FR)

(21) Appl. No.: 15/760,100

(22) PCT Filed: Sep. 13, 2016
(86) PCT No.: PCT/EP2016/071482

§ 371 Date: Mar. 14, 2018

Related U.S. Application Data
(60) Provisional application No. 62/218,401, filed on Sep. 14, 2015.

(51) Int. Cl. H01R 13/70; H01R 13/717; H01R 13/641; H01R 24/86; H01R 13/66; H01R 13/14; H01R 13/46; H05K 1/18

(52) U.S. Cl. CPC H01R 13/70; H01R 13/7175; H01R 13/641; H01R 24/86; H05K 2201/10106; H01R 13/14; H01R 13/465; H01R 13/6691; H05K 1/18; H01R 13/6658

(57) ABSTRACT

Electrical socket connector (10) for pluggable connection to a complementary plug connector (40), comprising a casing (11), a connection terminal assembly (13) mounted in the casing for connection to a complementary connection terminal assembly (43) of the plug connector, an identification system for identification of the plug connector, and an electronic switch (32) for secure connection between the socket and plug connectors. The identification system comprises a display unit (12) for connection status and a processing unit configured to read a plug identifier provided by an identifier module (46) of the plug connector each time the socket and plug connectors are connected together, and to control the electronic switch and the visual aspect of the display unit based on the plug identifier output.

### FIELD OF THE INVENTION

The present invention relates to a connector assembly with identification capabilities for secure connection, and more particularly to a connector assembly comprising smart socket and plug connectors. The invention also relates to an identification method for secure connection between plug and socket connectors and to a connection history control method for secure connection between a socket connector and a disposable plug connector particularly adapted for use in sterilized environment such as in hospitals.

### BACKGROUND OF THE INVENTION

Connectors are used in various fields of industry such as equipment registration, original equipment manufacturer authentication, peripheral and accessory identification, military applications and medical equipment identification. Connection security and customizable features through the connectors themselves are however not sufficiently addressed by the prior art. Conventional connectors are for instance not well adapted for use in a sterilized environment such as in hospitals where the lifespan of plug connectors may significantly be reduced by premature wear caused by aggressive chemical composition used for sterilization. Once the connectors have been sterilized, they need to be thoroughly rinsed with sterile water in order to remove residual solution to prevent premature wear which may cause defective functioning to the connector. After sterilization, devices must be track and restocked. For prior art connectors used in surgical equipment, problem of inventory control, cross-infection risks, and operational inefficiency are part of the constant sterilization and restocking process.

### SUMMARY OF THE INVENTION

In view of the forgoing, it is an object of the invention to provide a connector assembly which is secure and reliable, and in particular that enables connection status display for plug connector identification.

It is advantageous to provide a connector assembly which enables the user to have immediate visual identification showing that a plug connector is securely connected and powered up.

For certain applications it is advantageous to provide a connector assembly which enables secure transfer of sensitive data and which can detect unauthorized or unapproved connectors.

For certain applications it is advantageous to provide a connector assembly that reduces cross-infection risks and streamlines tracking, restocking and inventory procedures.

For certain applications it is advantageous to provide a socket connector that provides information on repetitive use of a disposable plug connector to prevent defective connections.

Various objects of this invention have been achieved by providing a socket connector according to claim 1.

Various objects of this invention have been achieved by providing the plug connector according to claim 24.

Various objects of this invention have been achieved by providing the connector assembly according to claim 25.

Various objects of the invention have been achieved by providing a method of establishing a secure authenticated connection between a socket connector and a plug connector according to claim 26.

Various objects of the invention have been achieved by providing a method of controlling a connection history between a socket connector and a disposable plug connector according to claim 27.

Disclosed herein is an electrical socket connector for pluggable connection to a complementary plug connector, including a casing, a connection terminal assembly mounted in the casing for connection to a complementary connection terminal assembly of the plug connector, and an identification system. The identification system comprises a processing unit configured to read a plug identifier provided by an identifier module of the plug connector each time the socket and plug connectors are connected together, and a display unit with a light source for displaying a connection status based on said plug identifier read by the processing unit.

According to an advantageous embodiment, the display is ring shaped and surrounds a plug receiving cavity of the casing.

According to an embodiment, the light source comprises an array of light emitting diodes (LEDs) mounted on a circuit board.

According to an embodiment, the display unit may comprise a transparent or translucent flange, the array of LEDs being mounted behind the transparent or translucent flange and configured to generate two or more colors, each color indicative of the connection status.

According to an embodiment, the array of LEDs may comprise a plurality of multi-color LEDs arranged in a circle, for instance a plurality of bi-color LEDs arranged in a circle. The transparent or translucent flange may thus also be ring shaped.

According to an embodiment, the display unit is engraved with text to show a specific backlit sign such as “ON” or “OFF”.

According to an embodiment, the socket connector further comprises supply wiring terminals mounted on the rear side of the connector for connecting the circuit board (e.g. printed circuit board) to a power source and to the ground.

According to an embodiment, the processing unit comprises a microcontroller comprising at least one input used to read the plug identifier received from the plug connector and at least two outputs used to control the light source of the display.

According to an embodiment, the socket connector may further comprise an electronic switch interconnected to one or more terminals of the connection terminal assembly, a microcontroller of the processing unit comprises an output connected to the electronic switch configured to control the electronic switch in order to connect or disconnect said one or more terminals based on the plug identifier read by said processing unit.

According to an embodiment, the electronic switch is in an open state prior to identification in which the socket and plug connectors are electrically disconnected from each other.

According to an embodiment, the processing unit comprises a circuit board on which said microcontroller, said electronic switch and said light source is mounted.

According to an advantageous embodiment, the circuit board is ring shaped.

According to an embodiment, the socket connector further comprises a heat sensor connected to the processing unit configured to monitor the temperature of the socket connector and to set the electronic switch to an open state when the temperature exceeds a predetermined value stored in a non-volatile memory of the connector.

According to an embodiment, the casing comprises an annular-shaped electronic components compartment surrounding a plug receiving cavity of the casing, the display unit having an annular shape and mounted in the electronic components compartment.

According to an embodiment, the processing unit comprises a non-volatile memory in which an identifier is pre-programmed, said identifier serving to authenticate said plug identifier.

According to an embodiment, the pre-programmed identifier may be a family identifier (ID) to authorize connection of a plurality of plugs having a plug identifier corresponding to said family ID.

According to an embodiment, the microcontroller of the processing unit may be configured to compare said read plug identifier with information received from the non-volatile memory and to process said information to approve or disapprove a connection by sending a voltage signal to the electronic switch and to the display.

According to an embodiment, a microcontroller of the processing unit may be configured to count a number of times a plug connector is plugged and unplugged from the socket connector and to store said number in a non-volatile memory of the processing unit.

According to an embodiment, the processing unit may be configured to distinguish between a number of times an authorized plug connector is plugged and unplugged from the socket connector from a number of times an unauthorized plug connector is plugged to the socket connector.

According to an embodiment, the processing unit may be configured to switch the electronic switch to an open state when said number reaches or exceeds a predetermined value stored in the non-volatile memory.

Also disclosed herein according to an aspect of the invention is an electrical socket connector for use in medical applications for pluggable connection to a complementary disposable plug connector, comprising a plug receiving portion, an identification and connection history control system for identification of the plug connector and for connection history control between the socket and plug connectors, and an electronic switch for secure authenticated connection between the socket and plug connectors, wherein the identification and connection history control system comprises a digital display unit for connection history status and a processing unit configured to read a plug identifier and an integer stored in a memory of the plug connector, said integer being correlated to the connection history between the socket and plug connectors, wherein the processing unit is further configured to modify the integer of the plug connector each time a secure connection is established between the socket and plug connectors, and to control the electronic switch and the digital display unit based on the plug identifier and integer outputs of the plug connector.

According to an embodiment, the electronic switch is in an open state prior identification in which the socket and plug connectors are electrically disconnected from each other and wherein the processing unit ensures that the electronic switch always remains is an open state when said integer reaches or exceeds a predetermined value.

Also disclosed herein according to an aspect of the invention is an electrical plug connector for pluggable connection to a socket connector according to any one of the preceding claims, the plug connector comprising an identifier module provided with a plug identifier and optionally a LED for displaying the connection status and/or a heat sensor.

Also disclosed herein according to an aspect of the invention is a connector pair assembly comprising the plug and socket connectors described above.

Also disclosed herein according to another aspect of the invention is a method of establishing a secure authenticated connection between a socket connector and a plug connector, comprising:

i) providing a socket connector and a plug connector;
ii) connecting the plug and socket connectors together;
iii) reading the plug identifier by the plug ID reader;
iv) controlling the electronic switch based on the read-out of the plug ID reader, and
v) setting the visual aspect of the display unit based on the read-out of the plug ID reader.

Also disclosed herein according to another aspect of the invention is a method of controlling secure connection history between a socket connector and a disposable plug connector, the socket connector comprising a plug ID reader and an electronic switch, the disposable plug connector comprising a plug identifier and a non-volatile memory in which is stored an integer representing a maximum number of allowed connection cycles between the plug connector and the socket connector, the method comprising the steps of:

i) connecting the plug and socket connectors together;
ii) reading of the plug identifier by the plug ID reader;
iii) determining whether the integer has reached a predetermined value if the read-out of plug ID reader is positive;
iv) modifying the integer stored in the memory of the plug connector each time a secure connection is established between the plug and socket connectors as long as the integer has not reached the predetermined value; and
v) setting the electronic switch to an open state when the integer has reached a predetermined value.

Further objects and advantageous effects of the invention will be apparent from the claims and from the following detailed description, and accompanying figures.

### BRIEF DESCRIPTION OF THE FIGURES

The invention will now be described with reference to the accompanying drawings which by way of examples illustrate embodiments of the present invention and in which:

FIG. 1 is a perspective view of a socket connector according to an embodiment of the invention;

FIG. 2 is a front view of the socket connector of FIG. 1;

FIG. 3 is an axial cross-sectional view of the socket connector of FIG. 1;

FIG. 4 is a side view of the socket connector of FIG. 1;

FIG. 5 is an exploded view of the socket connector of FIG. 1;

FIG. 6 is a perspective view of the socket connector of FIG. 1 connected to a driving board according to an embodiment of the invention;

FIG. 7 is a cross-sectional view of a plug connector for mating with the socket connector of FIG. 1 according to an embodiment of the invention;

FIG. 8 is a schematic view of a connection between a plug and a socket connector according to an embodiment of the invention;

FIG. 9 is a flowchart of an identification method for secure connection based on serial number comparison according to an embodiment of the invention;

FIG. 10 is a flowchart of a connection history control method for use in particular in a sterilized environment according to an embodiment of the invention; and

FIG. 11 is a flowchart of an identification method with electronic safeguards.

### DETAILED DESCRIPTION OF THE INVENTION

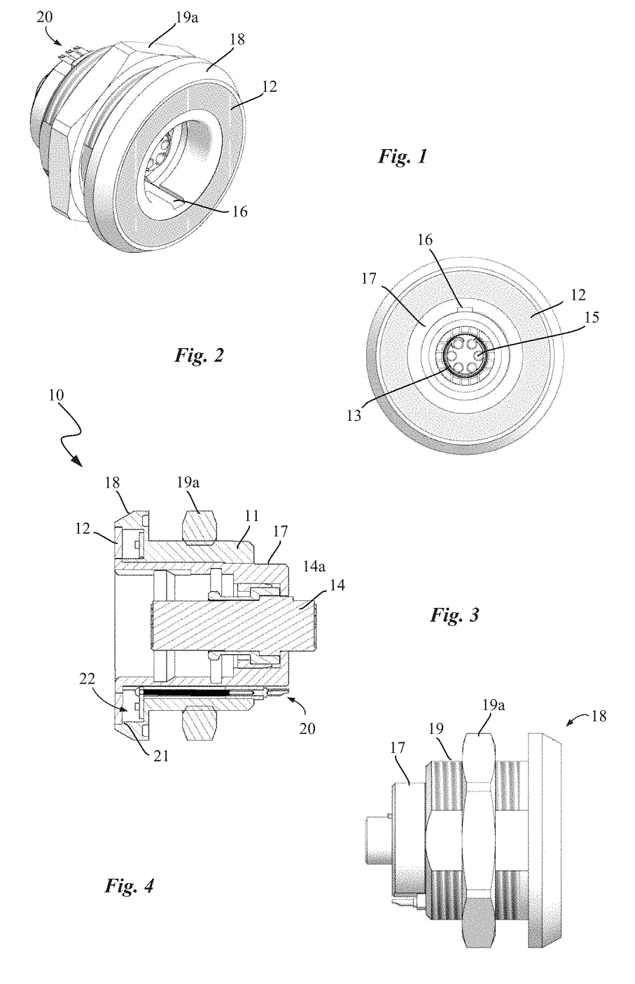

Referring to the figures, starting in particular with FIGS. 3 and 5, a socket connector 10 comprises a casing 11, a tubular sleeve 17 fitted inside the casing, an annular display unit 12 (FIGS. 1 & 2) which is transparent or translucent for displaying a wide spectrum of colors, and a connection terminal assembly 13 comprising a terminal housing 14 axially mounted within the tubular sleeve 17 and assembled therewith by means of a collet 14a. The terminal housing 14 is provided with receptacle terminals 15 for mating with pin contacts 41 partially mounted inside a terminal housing 42 of a complementary connection terminal assembly 43 of a plug connector 40 (FIG. 7) so as to ensure electrical connection between the plug and socket connectors when connected together.

The orientation and guiding of the socket connector 10 relative to the plug connector 40 is provided by a polarizing arrangement to ensure that the complementary connectors can only be plugged together in a certain angular orientation. The polarizing arrangement comprises a linear groove 16 arranged on the inner surface of the tubular sleeve 17 and adjacent the connection terminal assembly 13 of the socket connector and a corresponding protruding part 44 located on the outer surface of a protecting shell 45 of the plug connector. The groove 16 extends from the front side of the connector up to the terminal assembly for guiding the pin contacts of the plug connector into the receptacles terminals of the socket connector.

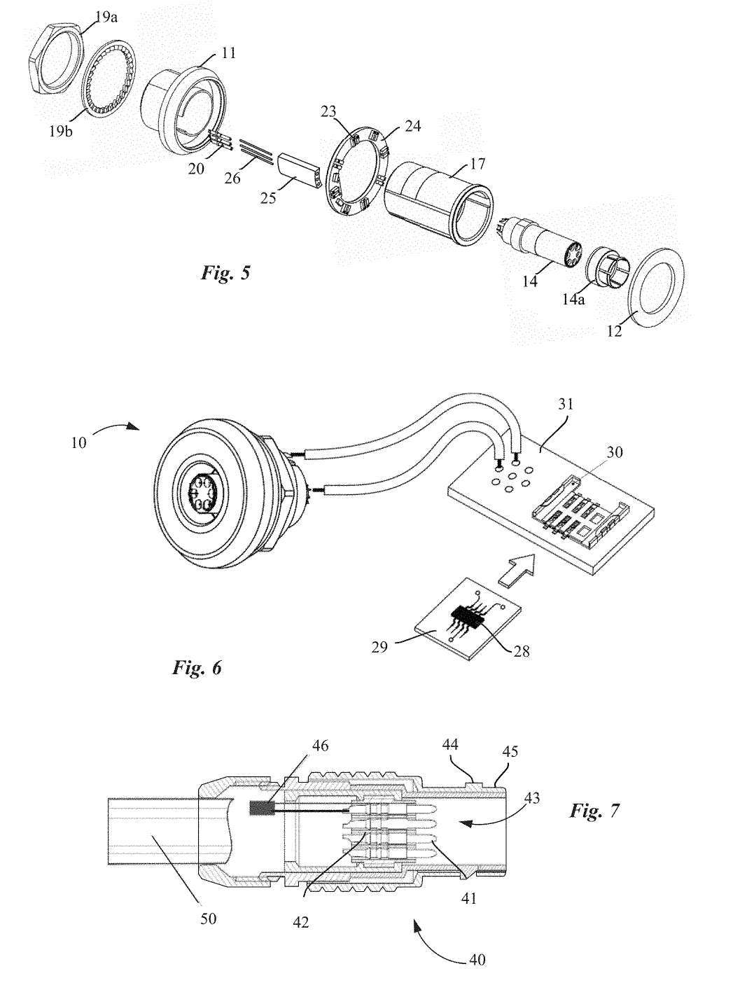

As best seen in FIG. 4, the casing comprises a flange 18 on the front side of the socket connector, a threaded exterior surface 19 for receiving a locknut 19a coupled to a washer 19b (FIG. 5) for fixing the socket connector to an electric/electronic device and power supply terminals 20 on the rear side of the connector. As shown in FIG. 3, the flange 18 comprises an annular recess provided with a ring shoulder 21 against which the annular display unit 12 is mounted to cover the entire recess thereby creating a substantially annular-shaped electronic components compartment 22 adjacent the display unit and which encloses a variety of electronic components.

In particular, several LEDs 23 of the display unit are mounted inside the electronic components compartment in order to display two different colors consecutively allowing the socket connector to indicate a connection status for diagnostics. In a preferred embodiment of the invention as shown in FIG. 5, bicolor LEDs (or tricolor LED's), configured to display preferably green and red colors, (or possibly white and red or other colors) are arranged behind the translucent flange of the display unit 12 on a printed circuit board 24 of general annular or ring shape such that an array of bicolor LEDs is arranged through 360° inside the electronic components compartment. The casing 11 comprises a cavity configured to receive a wire housing 25 comprising wires 26 which connect the annular circuit board 22 to the power supply terminals for connecting LEDs and other electronic components to a power source and to ground. The array of LEDs is driven as discussed below in detail so as to indicate whether.
a secure (i.e authenticated) connection between the plug and socket connectors has been established through an identification method according to an embodiment of the invention, or
a predetermined number of secure connection cycles between a disposal plug connector and a socket connector has been reached through an identification and connection history control method according to an embodiment of the invention.

In an advantageous embodiment, a microcontroller and a non-volatile memory 27 (FIG. 8), e.g. an EEPROM, are mounted inside the electronic components compartment on the printed circuit board of the socket connector. In a variant illustrated in FIG. 6, a microcontroller 28 may be mounted on a support 29 configured to be fitted on a support holder 30 of a separate driving board 31 connected to the socket connector 10. The driving board may be installed preferably in an electronic/electric device/equipment coupled to the socket connector.

Referring to FIGS. 7 and 8, the plug connector 40 is configured to be connected to an electrical cable or optical fiber 50 and comprises a non-volatile memory 46, such as EEPROM, electrically connected to at least one of the pin contacts 41 to allow a two-way communication between the microcontroller of the socket connector and the non-volatile memory of plug connector after plugging. The non-volatile memory 46 is pre-programmed with an identifier such as a serial number format (e.g. 48 bit serial number format) which is specific to a matching pair of plug and socket connectors. Advantageously, an electronic switch, for instance in the form of a relay 32, may be mounted on the printed circuit board inside the electronic components compartment of the socket connector. The relay is configured to be in an open state in which the socket connector is electrically disconnected from the plug connector or in a close state allowing a secure connection for transmission of sensitive data when the plug and socket connectors are connected together. The use of a relay allows the transfer of any kind of signal such as high speed data signal or high voltage signal and is particularly suited for the transmission of high volumes of data through optical fiber. Alternatively, the electronic switch may comprise a logic gate to perform the switching function

An identifier family can be pre-programmed on the non-volatile memory of multiple plug and socket connectors thus allowing multitude plug connectors to be securely connected (i.e. in an authenticated manner) to multiple socket connectors sharing the same identifier family.

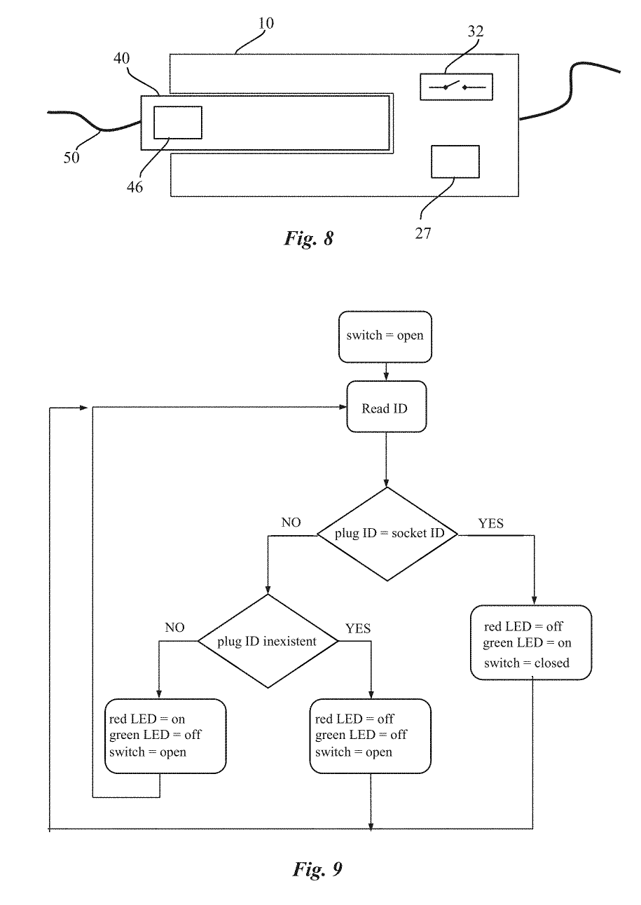

Referring now to FIG. 9, the electronic switch is generally configured to be in an open state prior coupling the plug connector with the socket connector. Connection between the plug and socket connectors triggers a signal ordering the microcontroller to determine whether the stored ID number in the plug's memory corresponds to the expected ID number. The ID number may be compared by the microcontroller with an ID number directly pre-programmed into the microcontroller or to an ID number stored in the non-volatile memory of the socket connector and retrieved by the microcontroller. If the two ID numbers match, the microcontroller sends a high voltage signal to the relay and to the array of green LEDs and a low voltage signal to the array of red LEDs thereby setting the relay to a close state allowing the transfer of secure data from the plug to the socket connectors on the one hand, and causing the display unit to turn green on the other hand. Conversely, if there is no match between the plug's ID number and the expected ID number, the microcontroller sends a low voltage signal to the relay and to the array of green LEDs and a high voltage signal to the array of red LEDs thereby causing the relay to remain open preventing the transfer of sensitive data between the plug and socket connectors on the one hand, and causing the display unit to turn red. In the configuration where the microcontroller cannot determine any valid ID number, the relay remains in an open state and the display unit remains red.

Accordingly, the secure connection through the identification method limits the use of the socket connector to all plug connectors comprising an ID number recognized by the microcontroller of the socket connector. The ID number may be stored in the non-volatile memory of the plug connector at the time of manufacture of the connector or at a later stage prior use.

In a preferred embodiment, the identification and connection history control method comprises a first stage of identification according to the above described method followed by a second stage in which the connection history between the plug and socket connectors is checked and in which the state of the relay of the socket connector is set according to the connection history status.

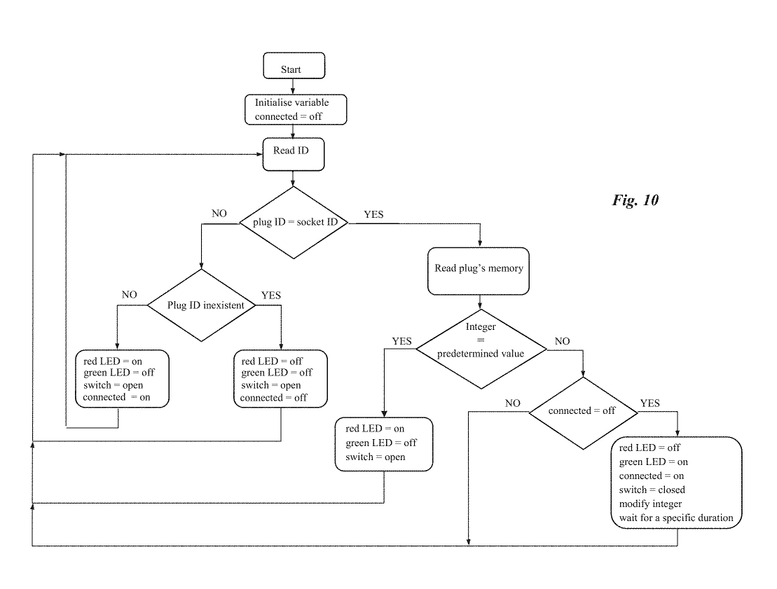

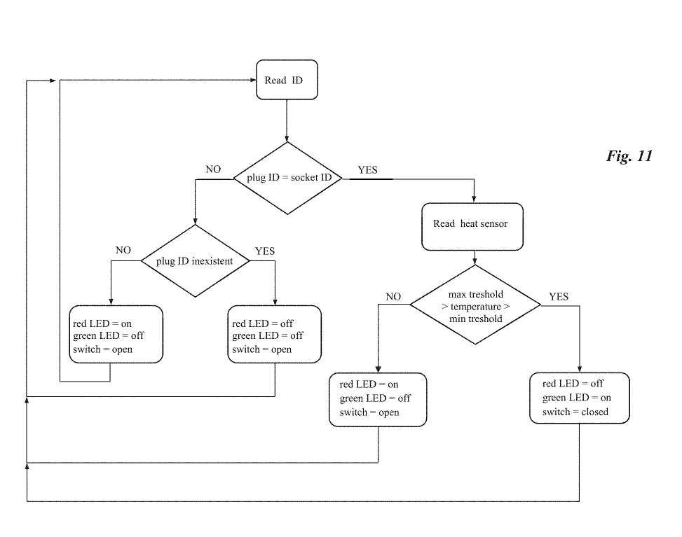

More particularly and with reference to FIG. 10, an integer (e.g. between 1 and 10) is stored in the non-volatile memory of the plug connector at the time of the manufacture or at a later stage prior use. This number corresponds advantageously to a maximum number of secure connection cycles that is possible to achieve with the plug connector prior disposal. A connection cycle must be understood within the context of the invention as an insertion of the plug connector into the socket connector with successful identification followed by the removal of the plug. This method is particularly suitable for connecting medical equipment used in sterilized environment where the lifespan of a plug connector is significantly reduced by premature wear caused by aggressive chemical compositions that can be corrosive to materials in case of repeated sterilization cycles.

When a plug connector, with an exemplary initial integer of 10 stored on its memory, is connected to the socket connector for the first time and after successful completion of the identification stage, the microcontroller reads the integer stored in the plug's memory and sends a high voltage signal to the relay and to the array of green LED's and a low voltage signal to the array of red LED's thereby setting the relay to a closed state allowing the transfer of secure data from the plug to the socket connectors on the one hand, and causing the display unit to turn green on the other hand. The microcontroller also sets the integer value at 9. In an advantageous embodiment, the microcontroller modifies the integer after a predefined period of time, in the order of a few milliseconds or microseconds, in order to ensure that micro-power cuts that may occur when connecting the plug and socket connectors together do not modify the integer. Once the predefined period of time has elapsed, the microcontroller verifies that the plug is connected by continuously checking the plug's ID number with the ID number(s) stored in a non-volatile memory of the socket connector, such that, as long as the plug connector remains connected, the microcontroller does not modify the integer stored in the plug's memory. In the configuration where the device to which the plug is connected is turned off and on, the microcontroller also modifies the integer stored in the plug's memory. When the integer reaches the predetermined value, after several connections between the plug and socket connectors, the microcontroller sends a low voltage signal to the relay and to the array of green LED's and a high voltage signal to the array of red LED's thereby setting the relay to an open state thus preventing further electrical connections between the socket connector and the disposal plug connector on the one hand, and causing the display unit to turn red on the other hand which indicates that the disposal plug connector may be discarded.

Advantageously, the array of LED's of the socket connector as described above is replaced by at least one digital display unit consisting of seven segments in order to display a countdown of the remaining connection cycles before disposal of the plug connector. The digital unit may display the letter “E” for error or “F” for failure when the predetermined value has been reached.

For this specific application, the socket connector comprises a cylindrical plug receiving portion and a digital display receiving portion comprising the digital display unit. The plug receiving portion and the digital display receiving portion form together a single-piece casing.

Referring to FIG. 11, the socket connector or the plug connector may also comprise a heat sensor configured to monitor the temperature of the connectors when coupled together and to set the electronic switch/relay to an open state when the temperature exceeds a predetermined value. In another embodiment, the plug connector may further comprise a light emitting diode (LED) for displaying the connection status and may be configured for pluggable connection with a computer for storing and/or retrieving sensitive data from the computer based on the identification method as previously described.

List of references

Socket-type connector 10

casing 11

electronic components compartment 22
tubular sleeve 17
flange 18

ring shoulder 21

threaded exterior surface 19
keying arrangement

key element e.g. groove, slot 16

connection terminal assembly 13

terminal housing 14
collet 14a
terminals 15

receptacle terminals

identification system (1emb)/ identification and connection history
control system (2emb)

processing unit

plug reader
microcontroller (1emb.)
memory 27

display unit 12/digital display

circuit board 24
light source

LED's 23
display electrical supply

power supply terminals 20

wire housing 25
wire 26

electronic switch

relay 32
logic gate

nut

locknut 19a
washer 19b

microcontroller 28 (1emb.)

support 29
support holder 30
driving board 31

heat sensor
Plug-type connector 40

protecting shell 45
complementary connection terminal assembly 43

terminal housing 42

pin contact 41

keying arrangement

complementary protruding part 44

identifier module

plug identifier

circuit component (e.g. integrated circuit)

non-volatile memory 46

ID code stored in memory

USB key
optical fiber 50

1-28. (canceled)

29. Electrical socket connector for pluggable connection to a complementary plug connector, including a casing, a connection terminal assembly mounted in the casing for connection to a complementary connection terminal assembly of the plug connector, and an identification system comprising a processing unit configured to read a plug identifier provided by an identifier module of the plug connector each time the socket and plug connectors are connected together and a display unit with a light source for displaying a connection status based on said plug identifier read by the processing unit.

30. Socket connector according to claim 29, wherein the display unit is ring shaped and surrounds a plug receiving cavity of the casing.

31. Socket connector according to claim 30, wherein the light source comprises an array of light emitting diodes (LEDs) mounted on a circuit board.

32. Socket connector according to claim 31, wherein the display unit comprises a transparent or translucent flange, the array of LEDs being mounted behind the transparent or translucent flange and configured to generate two or more colors, each color indicative of the connection status.

33. Socket connector according to claim 32, wherein the array of LEDs comprises a plurality of multi-color LEDs arranged in a circle.

34. Socket connector according to claim 29, wherein the display unit is engraved with text to show a specific backlit sign such as “ON” or “OFF”.

35. Socket connector according to claim 29, further comprising supply wiring terminals mounted on the rear side of the connector for connecting the circuit board to a power source and to the ground.

36. Socket connector according to claim 29, wherein the processing unit comprises a microcontroller comprising at least one input used to read the plug identifier received from the plug connector and at least two outputs to control the light source of the display.

37. Socket connector according to claim 29, further comprising an electronic switch interconnected to one or more terminals of the connection terminal assembly, a microcontroller of the processing unit comprises an output connected to the electronic switch configured to control the electronic switch in order to connect or disconnect said one or more terminals based on the plug identifier read by said processing unit.

38. Socket connector according to claim 37, wherein the electronic switch is in an open state prior to identification in which the socket and plug connectors are electrically disconnected from each other.

39. Socket connector according to claim 37, wherein the processing unit comprises a circuit board on which said microcontroller, said electronic switch, and said light source is mounted.

40. Socket connector according to claim 39, wherein the circuit board is ring shaped.

41. Socket connector according to claim 37, further comprising a heat sensor connected to the processing unit configured to monitor the temperature of the socket connector and to set the electronic switch to an open state when the temperature exceeds a predetermined value stored in a non-volatile of the connector.

42. Socket connector according to claim 29, wherein the casing comprises an annular-shaped electronic components compartment surrounding a plug receiving cavity of the casing, the display unit having an annular shape and mounted in the electronic components compartment.

43. Socket connector according to claim 29, wherein the process unit comprises a non-volatile memory in which an identifier is pre-programmed, said identifier serving to authenticate said plug identifier.

44. Socket connector according to claim 43, wherein said pre-programmed identifier is a family identifier (ID) to authorize connection of a plurality of plugs having a plug identifier corresponding to said family ID.

45. Socket connector according to claim 43, wherein the microcontroller of the processing unit is configured to compare said read plug identifier with information received from the non-volatile memory and to process said information to approve or disapprove a connection by sending a voltage signal to the electronic switch and to the display.

46. Socket connector according to claim 37, wherein a microcontroller of the processing unit is configured to count a number of times a plug connector is plugged and unplugged from the socket connector and to store said number in a non-volatile memory of the processing unit.

47. Socket connector according to claim 46, wherein the processing unit is configured to distinguish between a number of times an authorized plug connector is plugged and unplugged from the socket connector from a number of times an unauthorized plug connector is plugged to the socket connector.

48. Socket connector according to claim 46, wherein the processing unit is configured to switch the electronic switch to an open state when said number reaches or exceeds a predetermined value in the non-volatile memory.

49. Electrical socket connector for use in medical applications for pluggable connection to a complementary disposable plug connector, comprising a plug receiving portion, an identification and connection history control system for identification of the plug connector and for connection history control between the socket and plug connectors, and an electronic switch for secure authenticated connection between the socket and plug connectors, wherein the identification and connection history control system comprises a digital display unit for connection history status and a processing unit configured to read a plug identifier and an integer stored in a memory of the plug connector, said integer being correlated to the connection history between the socket and plug connectors, wherein the processing unit is further configured to output a signal to modify the integer of the plug connector each time a secure connection is established between the socket and plug connectors, and to control the electronic switch and the digital display unit based on the plug identifier and integer outputs of the plug connector.

50. Socket connector according to claim 49, wherein the electronic switch is in an open state prior identification in which the socket and plug connectors are electrically disconnected from each other and wherein the processing unit ensures that the electronic switch always remains in an open state when said integer reaches or exceeds a predetermined value.

51. Socket connector according to claim 49, including a casing, a connection terminal assembly mounted in the casing for connection to a complementary connection terminal assembly of the plug connector, and said identification system comprising a processing unit configured to read a plug identifier provided by an identifier module of the plug connector each time the socket and plug connectors are connected together and a display unit with a light source for displaying a connection status based on said plug identifier read by the processing unit, wherein the casing comprises an annular-shaped electronic components compartment (surrounding a plug receiving cavity of the casing, the display unit having an annular shape and mounted in the electronic components compartment.

52. Electrical plug connector for pluggable connection to a socket connector according to claim 29, the plug connector comprising an identifier module provided with a plug identifier and optionally a LED for displaying the connection status and/or a heat sensor.

53. Connector pair assembly comprising the socket connector according to claim 29 and a plug connector according to claim 52.

54. Method of establishing a secure authenticated connection between a socket connector and a plug connector, comprising:
i) providing a socket connector according to claim 29 and a plug connector according to claim 52;
ii) connecting the plug and socket connectors together;
iii) reading the identifier by the plug ID reader;
iv) controlling the electronic switch based on the read-out of the plug ID reader; and
v) setting the visual aspect of the display unit based on the read-out of the plug ID reader.

55. Method of controlling secure connection history between a socket connector and a disposable plug connector, the socket connector comprising a plug ID reader and an electronic switch, the disposable plug connector comprising a plug identifier and a non-volatile memory in which is stored an integer representing a maximum number of allowed connection cycles between the plug connector and the socket connector, the method comprising the steps of:
i) connecting the plug and socket connectors together;
ii) reading of the plug identifier by the plug ID reader;
iii) determining whether the integer has reached a predetermined value if the read-out of plug ID reader is positive;
iv) modifying the integer stored in the memory of the plug connector each time a secure connection is established between the plug and socket connectors as long as the integer has not reached the predetermined value; and
v) setting the electronic switch to an open state when the integer has reached a predetermined value.

56. Method according to claim 55, further comprising providing a socket connector including a casing, a connection terminal assembly mounted in the casing for connection to a complementary connection terminal assembly of the plug connector, and said identification system comprising a processing unit configured to read the plug identifier provided by an identifier module of the plug connector each time the socket and plug connectors are connected together and a display unit with a light source for displaying a connection status based on said plug identifier read by the processing unit, wherein the casing comprises an annular-shaped electronic components compartment (surrounding a plug receiving cavity of the casing, the display unit having an annular shape and mounted in the electronic components compartment).
